(19) United States
(12) Patent Application Publication
(10) Pub. No.: US 2012/0247532 A1
(43) Pub. Date: Oct. 4, 2012

(54) SOLAR CELL PANEL

(75) Inventors: Kuo-Shih LIU, Taipei City (TW); Keh-Yao Wang, Tainan City (TW); Yan-Xing Shen, Tainan City (TW)

(73) Assignee: Gloria Solar Co., Ltd., Tainan City (TW)

(21) Appl. No.: 13/077,207

(22) Filed: Mar. 31, 2011

(51) Int. Cl. H01L 31/052

(52) U.S. Cl. 136/246

(57) ABSTRACT

A solar cell panel is provided. The solar cell panel includes a solar cell module and a transparent substrate. The solar cell module includes a number of solar cells having a number of gaps. Each gap is located between any adjacent two of the solar cells. A transparent substrate is disposed above the solar cell module. The transparent substrate has a patterned structure which is right above the gaps. The progressing direction of a light ray is changed after the light ray passes through the patterned structure

### BACKGROUND OF THE INVENTION

1. Field of the Invention

The invention relates in general to a solar cell panel, and more particularly to a solar cell panel with high energy conversion efficiency.

2. Description of the Related Art

One of the most popular and important topics in last years is energy saving. The traditional energy source, like petroleum or natural gas, is limited. The traditional energy source will be exhausted one day. Besides, the burning of the traditional energy source produces much exhausted gases which cause greenhouse effect. Therefore, it is necessary to explore clean and inexhaustible energy to overcome the energy and environment crisis.

The solar energy is one of the best alternative energy candidates. Solar energy is an abundant renewable energy source. It has been estimated that the sun deposits more than 12,000 terawatts (TW) of energy on earth, which is large compared to the 13 TW of total current power consumption worldwide. Thus, converting even 0.1% of the sunlight into useful electricity could gain much more energy. A lot of various solar panels are provided and widely applied in recent decades. But the conversion efficiency from sunlight energy to useful electrical energy is still not good enough in the solar panels. Therefore, it is a subject of the industrial endeavors to improve the conversion efficiency of the solar panels.

### SUMMARY OF THE INVENTION

The invention is directed to a solar cell panel. The solar cell panels have high energy conversion efficiency.

According to an aspect of the present invention, a solar cell panel is provided. The solar cell panel comprises a solar cell module and a transparent substrate. The solar cell module comprises a number of solar cells having a number of gaps. Each gap is located between any adjacent two of the solar cells. A transparent substrate is disposed above the solar cell module. The transparent substrate has a patterned structure which is right above the gaps. The progressing direction of a light ray is changed after the light ray passes through the patterned structure.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 is a cross-sectional view showing a structure of a solar cell panel according to an embodiment of this disclosure.

FIG. 2A is a top view showing the solar cells in FIG. 1.

FIG. 2B is a top view showing the transparent substrate in FIG. 1.

FIG. 2C is a top view showing the transparent substrate and the solar cells in FIG. 1.

FIG. 3A-3F are cross-sectional views along dash line Y-Y′ in FIG. 2B according to different embodiments of this disclosure.

FIG. 4A-4F are cross-sectional views along the dash line Z-Z′ in FIG. 2B according to different embodiments of this disclosure.

FIG. 5 is a top view showing another embodiment of solar cell panel.

FIG. 6 is a top view showing still another embodiment of the solar cell panel.

FIG. 7A is a top view of another embodiment showing the solar cells in FIG. 1.

FIG. 7B is a top view of another embodiment showing the transparent substrate in FIG. 1.

FIG. 7C is a top view of another embodiment showing the transparent substrate and the solar cells in FIG. 1.

### DETAILED DESCRIPTION OF THE INVENTION

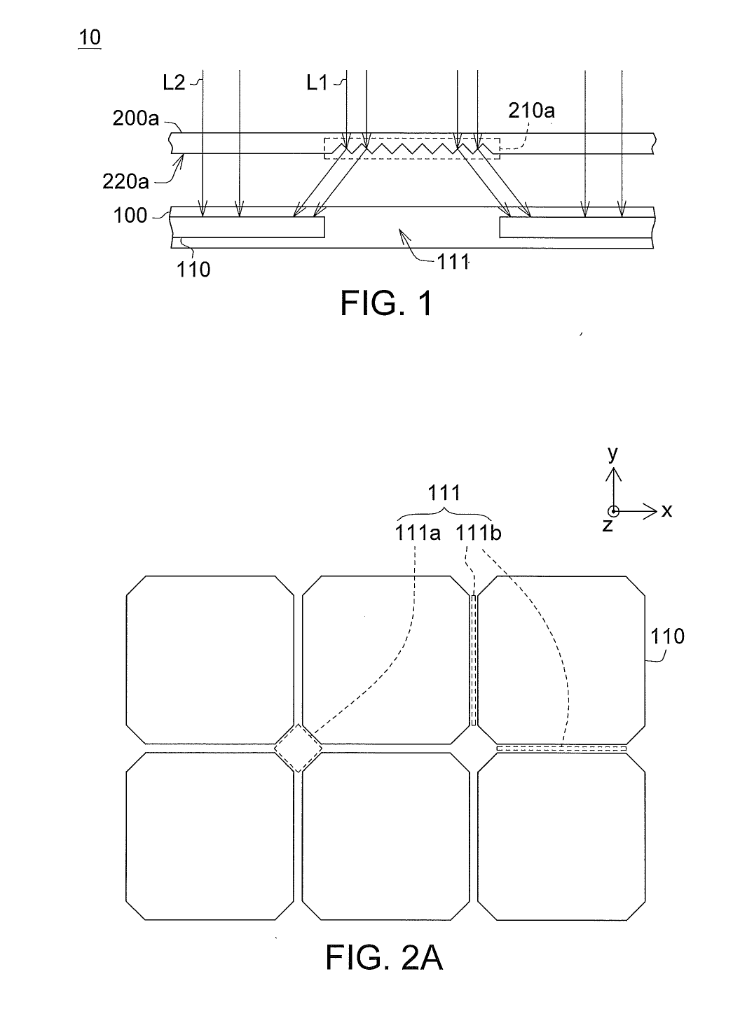

FIG. 1 is a cross-sectional view showing a structure of a solar cell panel according to an embodiment of this disclosure. A solar cell panel 10 includes a solar cell module 100 and a transparent substrate 200a. The solar cell module 100 includes a number of solar cells 110 which have a number of gaps 111. Each gap 111 is located between any adjacent two of the solar cells 110. The transparent substrate 200a is disposed above the solar cell module 100. The transparent substrate 200a has a surface 220a and includes a patterned structure 210a which is substantially right above the gaps 111. The progressing direction of a light ray L1 is changed after the light ray L1 passes through the patterned structure 210a. For example, the light ray L1 which passes through the patterned structure 210a will reach the solar cells 110 instead of the gaps 111. In this way, not only the light ray L1 but also the light ray L2 which is directed to the solar cells 110 reach the solar cells 110 and they are converted to useful electricity. Thus, the solar cell panel 10 of the embodiment sufficiently utilizes almost all the light L1 and L2 to transform the light energy into electrical energy.

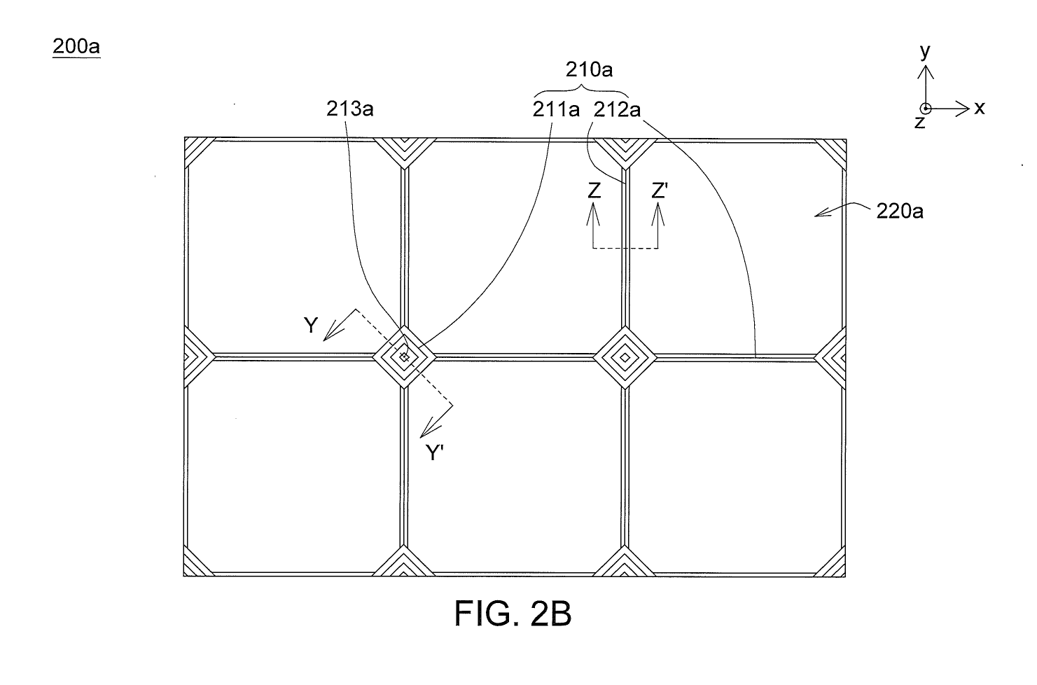

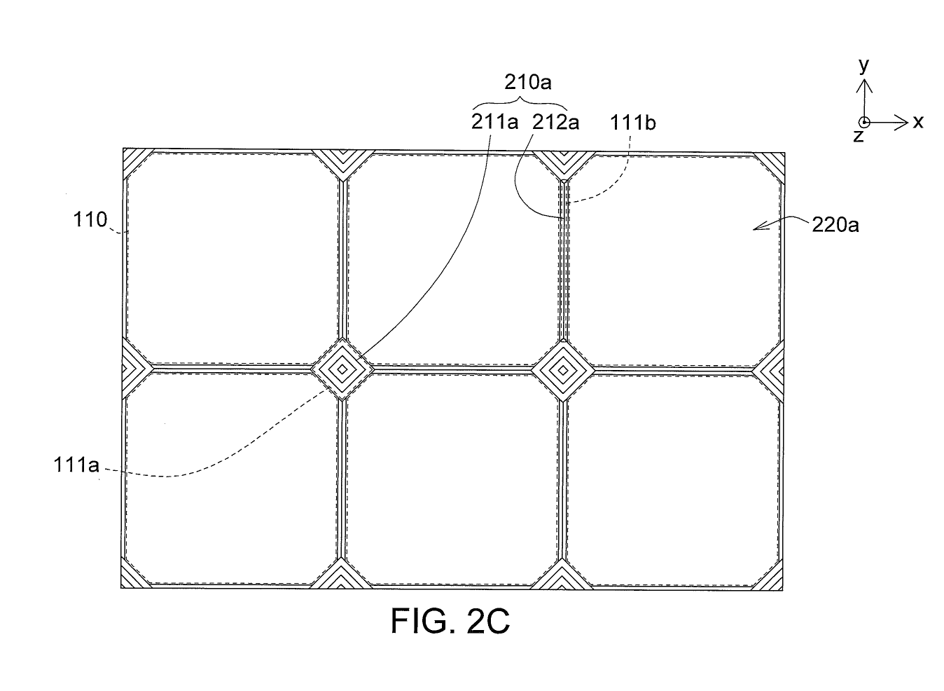

FIG. 2A is a top view showing the solar cells in FIG. 1. The gaps 111 have a number of diamond shaped gaps 111a and rod shaped gaps 111b. Each diamond shaped gap 111a may be formed by four adjacent solar cells 110 as shown in FIG. 2A. Besides, each rod shaped gap 111b may be formed by two adjacent solar cells 110 as shown in FIG. 2A. Each rod shaped gap 111b may be between two adjacent diamond shaped gap 111a.

FIG. 2B is a top view showing the transparent substrate in FIG. 1. The patterned structure 210a has a number of polygonal sub-structures 211a and a number of rod shaped sub-structures 212a formed on the surface 220a. Each solid line of the polygonal sub-structures 211a and the rod shaped sub-structures 212a represents a sub-structure. The surface 220a may be top or bottom surface of the transparent substrate 200a. In this embodiment, the surface 220a is the bottom surface. In this embodiment, the polygonal sub-structures 211a is, for example, implemented by a number of diamond shaped sub-structures 211a. The diamond shaped sub-structures 211a may have substantially the same center 213a. Besides, the rod shaped sub-structures 212a are substantially parallel to each other. In this embodiment, some rod shaped sub-structures 212a are substantially parallel to x-axis while the other rod shaped sub-structures 212a are substantially parallel to y-axis.

FIG. 2C is a top view showing the transparent substrate and the solar cells in FIG. 1. The diamond shaped sub-structures 211a may be disposed right above the diamond shaped gaps 111a. The rod shaped sub-structures 212a are disposed right above the rod shaped gaps 111b. In this way, almost all the light which passes through the patterned structure 210a may reach the solar cells 110. That is, almost all the light which passes through the transparent substrate 200a may be utilized by the solar cells 110 to improve the energy conversion efficiency of the solar cells 110.

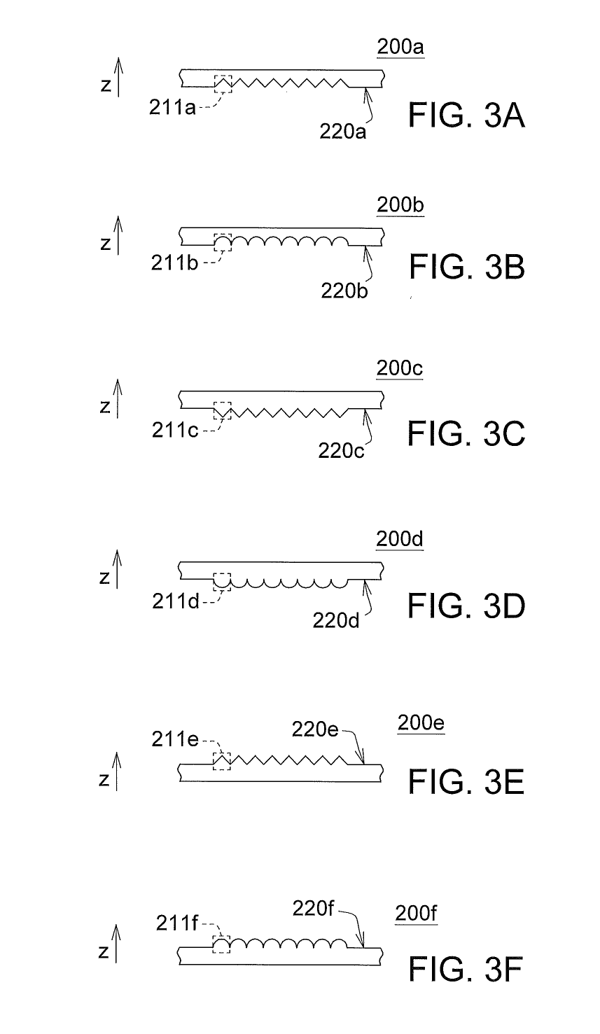

FIG. 3A is a cross-sectional view along the dash line Y-Y′ in FIG. 2B. FIG. 3A shows that the transparent substrate 200a has eight polygonal sub-structures 211a for example, however, the invention is not limited thereto. A cross-section of each polygonal sub-structure 211a along a vertical direction (e.g. z-axis direction) of the surface 220a is a triangle. The surface 220a is the bottom surface of the transparent substrate 200a. Each polygonal sub-structure 211a may be adjacent to each other. The polygonal sub-structures 211a are concaved with respect to the surface 220a.

FIG. 3B is a cross-sectional view along dash line Y-Y′ in FIG. 2B according to another embodiment of this disclosure. A cross-section of each polygonal sub-structure 211b along a vertical direction (e.g. z-axis direction) of the surface 220b is curve-edged. The curve-edged can be part of circle or oval-shaped edge. In FIG. 3B, the surface 220b is the bottom surface of the transparent substrate 200b. Each polygonal sub-structure 211b may be adjacent to each other. The polygonal sub-structures 211b are concaved with respect to the surface 220b.

FIG. 3C is a cross-sectional view along dash line Y-Y′ in FIG. 2B according to still another embodiment of this disclosure. A cross-section of each polygonal sub-structure 211c along a vertical direction (e.g. z-axis direction) of the surface 220c is a triangle. In FIG. 3C, the surface 220c is the bottom surface of the transparent substrate 200c. Each polygonal sub-structure 211c may be adjacent to each other. The polygonal sub-structures 211c protrude from the surface 220c.

FIG. 3D is a cross-sectional view along dash line Y-Y′ in FIG. 2B according to another embodiment of this disclosure. A cross-section of each polygonal sub-structure 211d along a vertical direction (e.g. z-axis direction) of the surface 220d is curve-edged. The curve-edged can be part of circle or oval-shaped edge. In FIG. 3D, the surface 220d is the bottom surface of the transparent substrate 200d. Each polygonal sub-structure 211d may be adjacent to each other. The polygonal sub-structures 211d protrude from the surface 220d.

FIG. 3E is a cross-sectional view along dash line Y-Y′ in FIG. 2B according to still another embodiment of this disclosure. A cross-section of each polygonal sub-structure 211e along a vertical direction (e.g. z-axis direction) of the surface 220e is a triangle. In FIG. 3E, the surface 220e is the top surface of the transparent substrate 200e. Each polygonal sub-structure 211e may be adjacent to each other. The polygonal sub-structures 211e protrude from surface 220e.

FIG. 3F is a cross-sectional view along dash line Y-Y′ in FIG. 2B according to another embodiment of this disclosure. A cross-section of each polygonal sub-structure 211f along a vertical direction (e.g. z-axis direction) of the surface 220f is curve-edged. In FIG. 3F, the surface 220f is the top surface of the transparent substrate 200e. Each polygonal sub-structure 211f may be adjacent to each other. The polygonal sub-structures 211f protrude from surface 220f. There still may be other alternatives of the transparent substrate by combining some embodiments above. For example, the polygonal sub-structure of still another embodiment may protrude from both the top and bottom surface of the transparent substrate at the same time.

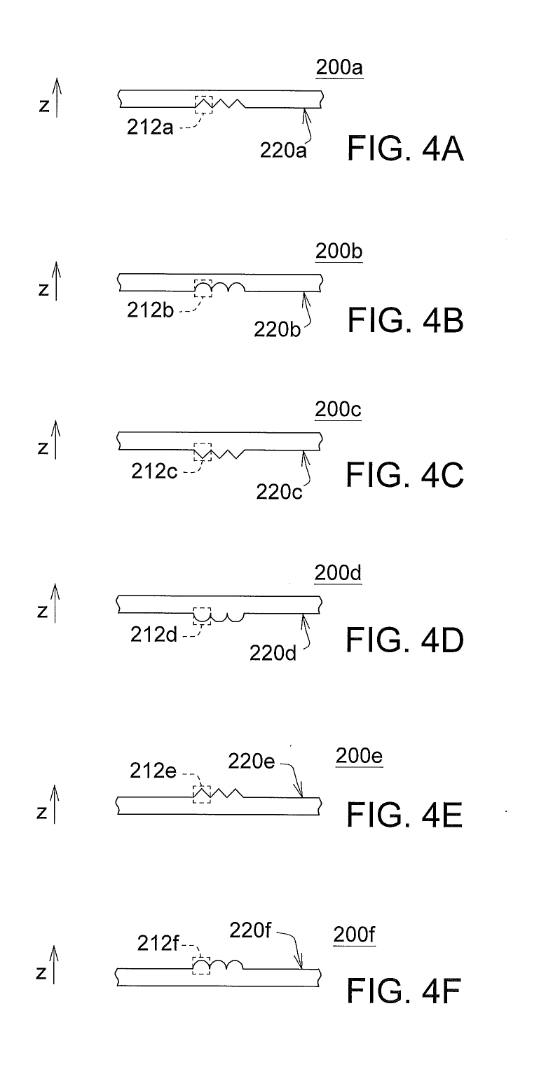

FIG. 4A is a cross-sectional view along the dash line Z-Z′ in FIG. 2B. The transparent substrate 200a has a number of rod shaped sub-structures 212a. A cross-section of each rod shaped sub-structure 212a along a vertical direction (e.g. z-axis direction) of the surface 220a is a triangle. The surface 220a is the bottom surface of the transparent substrate 200a. Each polygonal sub-structure 212a may be adjacent to each other. The polygonal sub-structures 212a are concaved with respect to the surface 220a. From above description, the structure of the sub-structure 212a is similar to the structure of sub-structures 211a. Also, the structures of the sub-structures from 212b to 212f as shown in FIGS. 4B to 4F are similar to the structures of the sub-structures from 211b to 211f respectively. Thus the similar parts does not be described again.

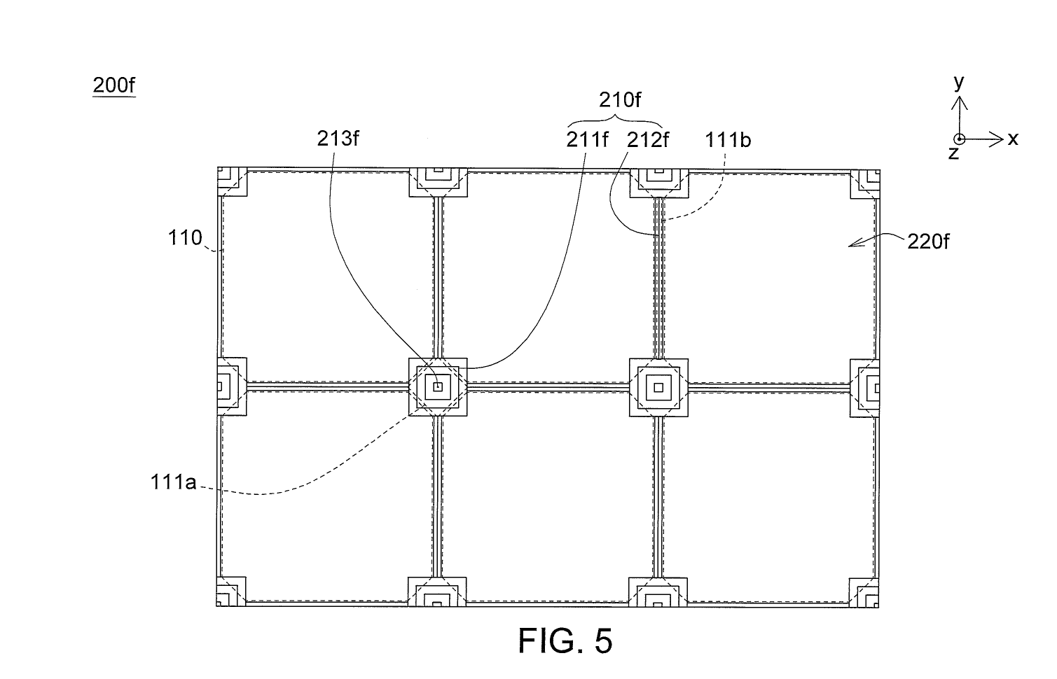

FIG. 5 is a top view showing another embodiment of solar cell panel. The transparent substrate 200f has a surface 220f. The patterned structure 210f has a number of polygonal sub-structures 211f formed on the surface 220f. The polygonal sub-structures 211f are square sub-structures 211f. The square sub-structures 211f have substantially the same center 213f. The square sub-structures 211f are substantially right above the diamond shaped gaps 111a. And the region of the square sub-structures 211f may be a little bit larger than the region of the diamond shaped gaps 111a in order to make sure that all the lights which pass through square sub-structures 211f may reach the solar cells 110. The transparent substrate 200f can have the same features of the previous embodiments and they will not be described repeatedly.

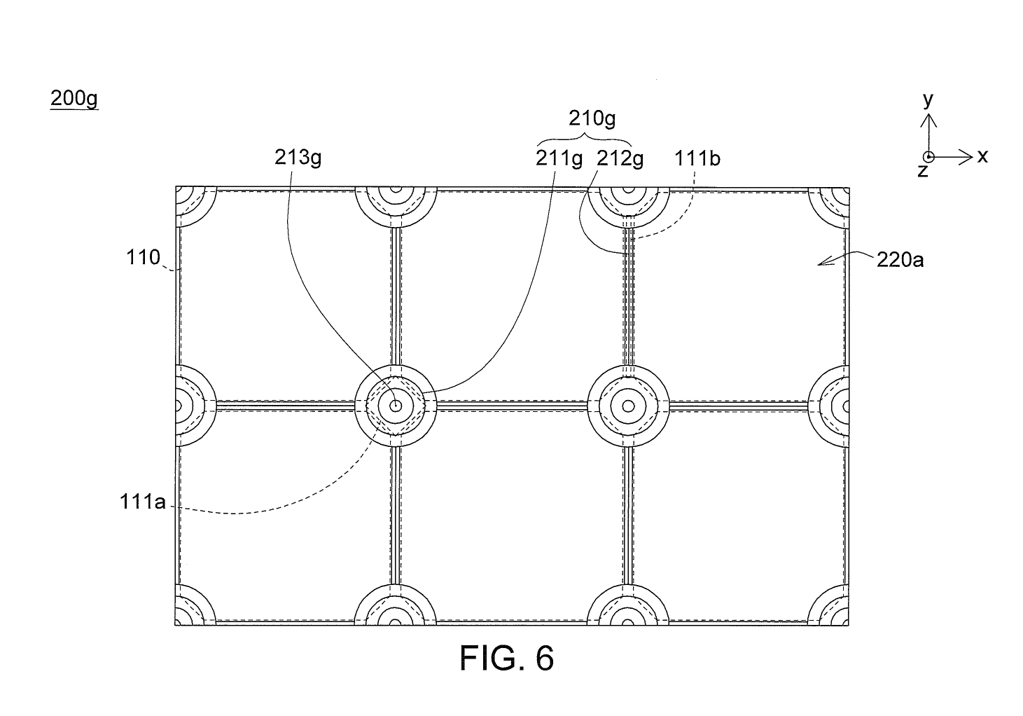

FIG. 6 is a top view showing still another embodiment of the solar cell panel. The transparent substrate 200g has a surface 220g. The patterned structure 210g has a number of circular sub-structures 211g formed on the surface 220g. The circular sub-structures 211g have substantially the same center 213g. The circular sub-structures 211g are substantially right above the diamond shaped gaps 111a. The region of the circular sub-structures 211g may be a little bit larger than the region of the diamond shaped gaps 111a in order to make sure that all the lights which pass through circular sub-structures 211g may reach the solar cells 110. The transparent substrate 200g can have the same features of the previous embodiments and they will not be described repeatedly.

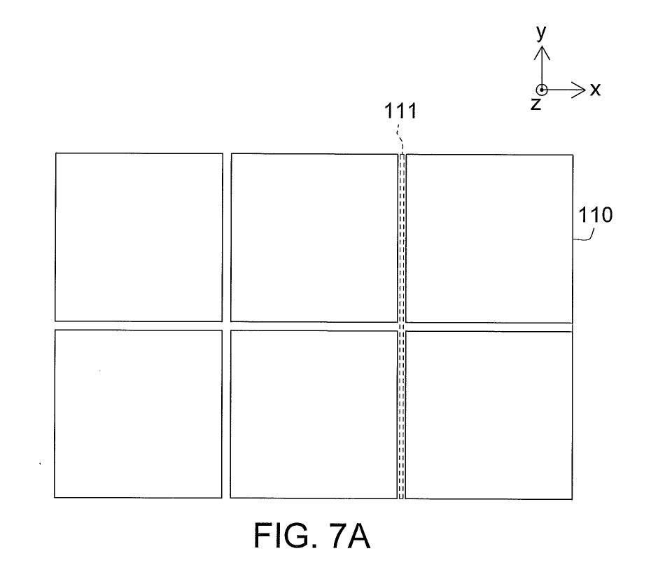

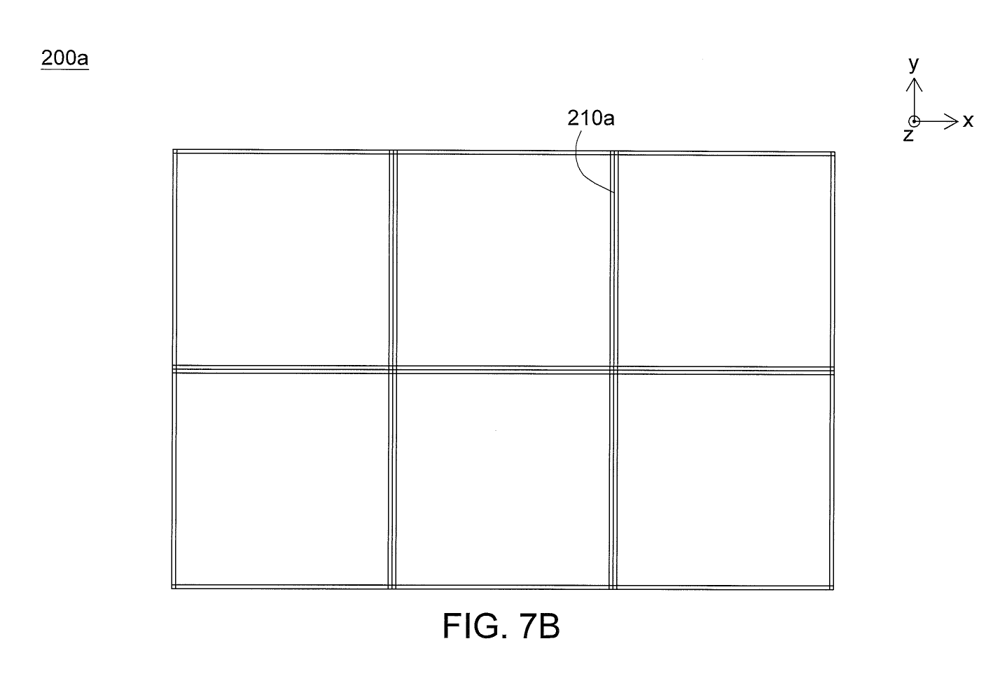

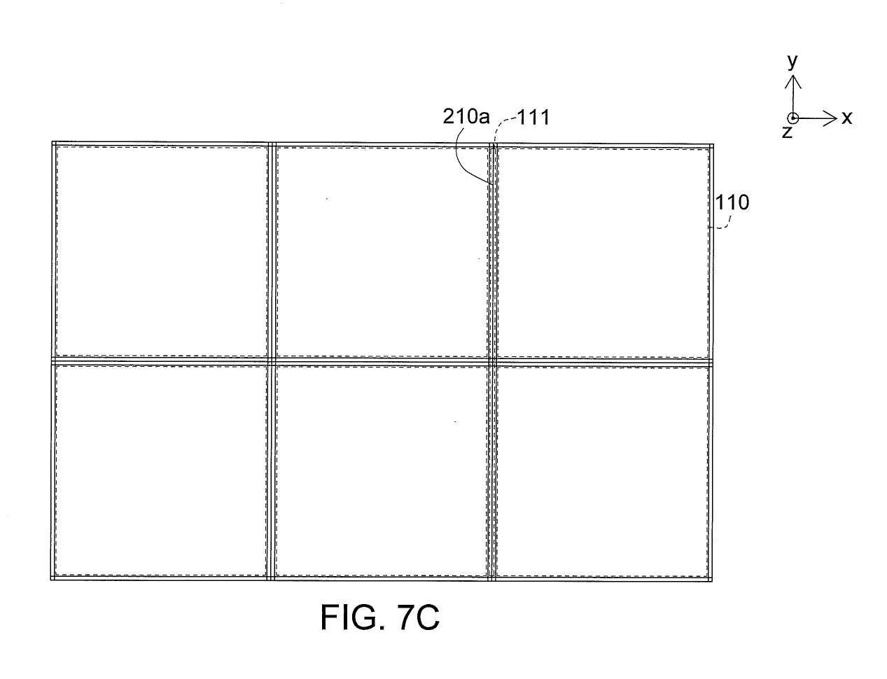

In another embodiment, the solar cells could be square. FIG. 7A is a top view of another embodiment showing the solar cells in FIG. 1. There are several gaps 111 formed between adjacent solar cells 110 as shown in FIG. 7A. FIG. 7B is a top view of another embodiment showing the transparent substrate in FIG. 1. Each solid line of the patterned structure 210a represents a sub-structure in the transparent substrate 200a. In this embodiment, some patterned structures 210a are substantially parallel to x-axis while the other patterned structures 210a are substantially parallel to y-axis.

FIG. 7C is a top view of another embodiment showing the transparent substrate and the solar cells in FIG. 1. The patterned structure 210a may be disposed right above the gaps 111. In this way, almost all the light which passes through the patterned structure 210a may reach the solar cells 110. Other parts of the embodiment are similar with the previous embodiment, thus the similar parts does not be described again.

Several transparent substrates which have different patterned structures are provided in the embodiments and described above. The progressing direction of the light ray which passes through the patterned structure may be changed. In this way, compared to normal flat transparent substrates in which the light ray corresponding to the gaps is not received by the solar cells and is wasted, the transparent substrates which include patterned structures may have more light rays transmitted to the solar cells. Because the solar cells receive more light rays, the energy conversion efficiency of the solar panels may be improved.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A solar cell panel, comprising:
a solar cell module, comprising a plurality of solar cells having a plurality of gaps, each gap being located between any adjacent two of the solar cells; and
a transparent substrate disposed above the solar cell module, the transparent substrate having a patterned structure which is right above the gaps, the progressing direction of a light ray being changed after the light ray passes through the patterned structure.

2. The solar cell panel according to claim 1, wherein the transparent substrate has a surface, and the patterned structure has a plurality of polygonal sub-structures formed on the surface.

3. The solar cell panel according to claim 2, wherein the gaps have a plurality of diamond shaped gaps, and the polygonal sub-structures are disposed right above the diamond shaped gaps.

4. The solar cell panel according to claim 3, wherein the polygonal sub-structures comprise a plurality of diamond shaped sub-structures, the diamond shaped sub-structures have substantially the same center.

5. The solar cell panel according to claim 2, wherein a cross-section of each polygonal sub-structure along a vertical direction of the surface is a triangle.

6. The solar cell panel according to claim 2, wherein a cross-section of each polygonal sub-structure along a vertical direction of the surface is curve-edged.

7. The solar cell panel according to claim 1, wherein the transparent substrate has a surface, and the patterned structure has a plurality of rod shaped sub-structures which are substantially parallel to each other formed on the surface.

8. The solar cell panel according to claim 7, wherein the gaps have a plurality of rod shaped gaps, and the rod shaped sub-structures are disposed right above the rod shaped gaps.

9. The solar cell panel according to claim 7, wherein a cross-section of each rod shaped sub-structure along a vertical direction of the surface is a triangle.

10. The solar cell panel according to claim 7, wherein a cross-section of each rod shaped sub-structure along a vertical direction of the surface is curve-edged.

11. The solar cell panel according to claim 1, wherein the patterned structure protrudes from the surface.

12. The solar cell panel according to claim 1, wherein the patterned structure is concaved with respect to the surface.

13. The solar cell panel according to claim 1, wherein the transparent substrate has a surface, and the patterned structure has a plurality of circular sub-structures formed on the surface, the circular sub-structures have substantially the same center.
